(19) United States
(12) Patent Application Publication
(10) Pub. No.: US 2024/0047289 A1
(43) Pub. Date: Feb. 8, 2024

(54) MOLDED POWER SEMICONDUCTOR MODULE AND METHOD FOR FABRICATING THE SAME

(71) Applicant: Infineon Technologies AG, Neubiberg (DE)

(72) Inventors: Marco Bässler, Oeversee (DE); Patrik Holt Jones, Soest (DE); Ludwig Busch, Erwitte (DE); Egbert Lamminger, Soest (DE)

(21) Appl. No.: 18/356,762

(22) Filed: Jul. 21, 2023

(30) Foreign Application Priority Data
Aug. 4, 2022 (DE) 102022119564.3
Aug. 4, 2022 (DE) 202022104434.1

(51) Int. Cl. H01L 23/31; H01L 21/56; H01L 23/48; H01L 23/495

(52) U.S. Cl. CPC H01L 23/3121; H01L 21/56; H01L 23/48; H01L 23/495; H01L 25/07

(57) ABSTRACT

A molded power semiconductor module includes: one or more power semiconductor dies; a molded body at least partially encapsulating each power semiconductor die and having opposing first and second sides, and lateral sides connecting the first and second sides; and first and second power contacts arranged laterally next to each other at a first one of the lateral sides of the molded body and electrically coupled to the power semiconductor die(s). The power contacts each have opposing first and second sides, each first side having an exposed part exposed from the molded body, each second side having a part that is arranged in a vertical direction below an outline of the respective exposed part of the first side and that is at least partially covered by a protrusion part of the molded body. The vertical direction is perpendicular to the first and second sides of the power contacts.

### TECHNICAL FIELD

This disclosure relates in general to a molded power semiconductor module as well as to a method for fabricating such a molded power semiconductor module.

### BACKGROUND

Power semiconductor modules may comprise an encapsulation, e.g. a molded body, as well as power contacts that are exposed from the encapsulation and that are configured to electrically couple the power semiconductor module to an external appliance. Fabricating a low inductance joint between the power contacts and the external appliance may for example comprise welding the power contacts to the external appliance. The power contacts may be mechanically pressed onto the external appliance during the fabrication of the joint. In order to prevent the power contacts from, taking damage or from bending out of shape due to the mechanical pressure, it may be necessary to take special care and/or to provide a dedicated support for the power contacts. This may e.g. increase the costs for installing the power semiconductor module. Furthermore, the power contacts of a power semiconductor module have to be arranged at a minimum distance relative to each other in order to ensure proper electrical isolation from one another. However, the larger this distance is the worse the inductance of the power semiconductor module may become. Improved molded power semiconductor modules as well as improved methods for fabricating molded power semiconductor modules may help to solve these and other problems.

The problem on which the invention is based is solved by the features of the independent claims. Further advantageous examples are described in the dependent claims.

### SUMMARY

Various aspects pertain to a molded power semiconductor module, comprising: one or more power semiconductor dies, a molded body at least partially encapsulating the one or more power semiconductor dies, the molded body having a first side, an opposite second side and lateral sides connecting the first and second sides, a first and a second power contact arranged laterally next to each other at first one of the lateral sides of the molded body and electrically coupled to the one or more power semiconductor dies, the first and second power contacts each comprising a first and an opposite second side, wherein the first sides of the first and second power contacts each comprise an exposed part exposed from the molded body, and wherein the second sides of the first and second power contacts comprise a part that is arranged vertically below an outline of the respective exposed part of the first side and that is at least partially covered by a protrusion part of the molded body, wherein the vertical direction is perpendicular to the first and second sides of the power contacts.

Various aspects pertain to a method for fabricating a molded power semiconductor module, the method comprising: providing one or more power semiconductor dies, electrically coupling a first and a second power contact to the one or more power semiconductor dies, the first and second power contacts each comprising a first and an opposite second side, and at least partially encapsulating the one or more power semiconductor dies with a molded body, wherein the molded body has a first side, an opposite second side and lateral sides connecting the first and second sides, such that the first and second power contacts are arranged at a first one of the lateral sides of the molded body, wherein the first sides of the first and second power contacts each comprise an exposed part exposed from the molded body, and wherein the second sides of the first and second power contacts comprise a part that is arranged vertically below an outline of the respective exposed part of the first side and that is at least partially covered by a protrusion part of the molded body, wherein the vertical direction is perpendicular to the first and second sides of the power contacts.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative so each other. Identical reference numbers designate corresponding similar parts.

FIGS. 1A and 1B show a plan view (FIG. 1A) and a sectional view (FIG. 1B) of a molded power semiconductor module, wherein a protrusion part of the molded body is arranged below and mechanically supports the power contacts.

FIG. 2 shows a sectional view of she molded power semiconductor module of FIGS. 1A and 1B according to a specific example.

FIG. 3 shows a sectional view of the molded power semiconductor module of FIGS. 1A and 1B according to another specific example.

FIG. 4 shows a perspective view of a further molded power semiconductor module which comprises the power contacts, the protrusion part of the molded body and also control or sensing contacts.

FIG. 5 shows a plan view of a further molded power semiconductor module which comprises the components shown in FIGS. 1A and 1B and which additionally comprises testing contacts.

FIG. 6 is a flow chart of an exemplary method for fabricating a molded power semiconductor module.

### DETAILED DESCRIPTION

In the following detailed description, directional terminology, such as “top”, “bottom”, “left”, “right”, “upper”, “lower” etc. , is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term. “exemplary” is merely meant as an example, rather than the best or optimal.

The examples of a molded power semiconductor module may use various types of semiconductor dies or circuits incorporated in the semiconductor dies, among them AC/DC or DC/DC converter circuits, power MOS transistors, power Schottky diodes, JFETs (Junction Gate Field Effect Transistors), power bipolar transistors, logic integrated circuits, analogue integrated circuits, mixed signal integrated circuits, sensor circuits, power integrated circuits, etc. The examples may also use semiconductor dies comprising MOSFET transistor structures or vertical transistor structures like, for example, IGBT (Insulated Gate Bipolar Transistor) structures or, in general, transistor structures in which at least one electrical contact pad is arranged on a first main face of the semiconductor die and at least one other electrical contact pad is arranged on a second main face of the semiconductor die, opposite to the first-main face of the semiconductor die.

An efficient molded power semiconductor module may for example reduce material consumption, ohmic losses, chemical waste, etc. and may thus enable energy and/or resource savings. Improved molded power semiconductor modules as well as improved methods for fabricating a molded power semiconductor module, as specified in this description, may thus at least indirectly contribute to green technology solutions, i.e. climate-friendly solutions providing a mitigation of energy and/or resource use.

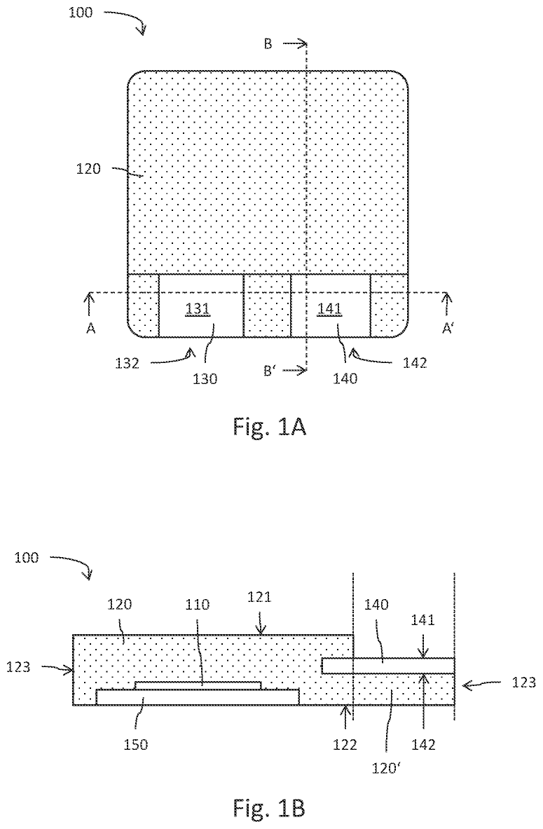

FIGS. 1A and 1B show a molded power semiconductor module 100. FIG. 1A shows a plan view and FIG. 1B shows a sectional view along the line B-B′ in FIG. 1A.

The molded power semiconductor module 100 comprises one or more power semiconductor dies 110, a molded body 120, a first power contact 130 and a second power contact 140.

The one or more power semiconductor dies 110 may be configured to operate with a high voltage and/or a strong electrical current. The one or more power semiconductor dies 110 may be electrically coupled to form any suitable type of electrical circuit, e.g. a converter circuit, an inverter circuit, a half-bridge circuit, etc.

In the case that the molded power semiconductor module 100 comprises more than one power semiconductor die 110, the power semiconductor dies 110 may all be of the same type or the power semiconductor dies 110 may be of different types.

According to an example, the molded power semiconductor module 100 comprises one or more carriers 150, wherein the one or more power semiconductor dies 110 are arranged on the carrier (s) 150. Each power semiconductor die 110 may be arranged on a separate carrier 150 or several of the power semiconductor dies 110 or all of the power semiconductor dies 110 may be arranged on the same carrier 150. The one or more carriers 150 may for example be power electronic substrates. The carrier (s) 150 may comprise a layer structure comprising at least one electrically conductive layer and at least one electrically isolating laver. The carrier (s) 150 may for example be of the type direct copper bond (DCB), direct aluminum bond (DAB), or active metal braze (AMB). According to another example, the carrier(s) 150 may be leadframe parts.

The power contacts 130, 140 may be electrically coupled to the carrier (s) 150 and/or to the power semiconductor die (s) 110 for example using electrical connectors like bond wires, ribbons or contact clips.

The molded body 120 at least partially encapsulates the one or more power semiconductor dies 110. The molded body 120 has a first side 121, an opposite second side 122 and lateral sides 123 connecting the first and second sides 121, 122.

The molded body 120 may comprise any suitable mold material. The molded body 120 may for example be fabricated by injection molding, transfer molding or compression molding. The molded body 120 may comprise filler particles, in particular inorganic filler particles configured to reduce the thermal resistance of the molded body 120.

As shown in FIG. 1B, the one or more carriers 150 may be exposed from the molded body 120 at the second side 122. However, it is also possible that the carrier (s) 150 are not exposed from the molded body 120.

The second side 122 of the molded body 120 may be configured to be arranged over a baseplate and/or a heatsink. The heatsink may be configured for air cooling or the heatsink may be configured to use a cooling fluid for direct or indirect liquid cooling of the molded power semiconductor module 100.

The first power contact 130 and the second power contact 140 are arranged laterally next to each other at a first one of the lateral sides 123 of the molded body 120. The molded power semiconductor module 100 may comprise only the two power contacts 130, 140 as shown in FIG. 1A. However, it is also possible that the molded power semiconductor module 100 comprises one or more further power contacts. The one or more further power contacts may be arranged laterally next to the first and second power contacts 130, 140 at the first one of the lateral sides 123 of the molded body 120. However, it is also possible that one or more further power contacts are arranged at one or more other ones of the lateral sides 123.

According to an example, the molded power semiconductor module 100 further comprises one or more control or sensing contacts. The control or sensing contacts may for example be arranged at the first side 121 of the molded body and/or at one of the lateral sides 123. The control or sensing contacts may for example comprise pins, in particular pressfit pins, or leadframe parts. The control or sensing contacts may be configured to couple the molded power semiconductor module 100 to an application board.

The first and second power contacts 130, 140 are electrically coupled to the one or more power semiconductor dies 110. The power contacts 130, 140 may e.g. be configured to provide a respective supply voltage to the power semiconductor die(s) 110. The respective supply voltage may for example be a positive or a negative supply voltage. However, it is also possible that the power contacts 130, 140 are configured as output contacts of the power semiconductor die(s) 110.

The power contacts 130, 140 may for example be leadframe parts. The power contacts 130, 140 may for example comprise or consist of Al, Cu or Fe. The power contacts 130, 140 may comprise a coating, e.g. a Ni coating.

The first and second power contacts 130, 140 each comprise a first side 131, 141 and an opposite second side 132, 142. The first sides 131, 141 of the first and second power contacts 130, 140 each comprise an exposed part exposed from the molded body 120. In FIG. 1B, the exposed part of the first side 141 of the second power contact 140 is framed by vertical dashed lines.

On the other hand, the second sides 132, 142 of the first and second power contacts 130, 140 comprise a part that is arranged vertically below an outline of the respective exposed part of the respective first side 131, 132. Furthermore, this part of the second sides 132, 142 is at least partially covered by a protrusion part 120′ of the molded body 120. In FIG. 1B, the protrusion part 120′ is that part of the molded body 120 that is arranged between the vertical dashed lines. The protrusion part 120′ may be contiguous with the rest of the molded body 120.

For example during installation of the molded power semiconductor module 100, it may be necessary to exert a mechanical force onto the power contacts 130, 140. The power contacts 130, 140 may for example be configured to be coupled (e.g. welded) to an external appliance like a bus bar. In order to create a firm joint, the power contacts 130, 140 may be pressed onto the bus bar during the welding process. The protrusion part 120′ of the molded body 120 may be configured to mechanically support the power contacts 130, 140 during this process and to prevent the power contacts 130, 140 from bending out of shape. The molded power semiconductor module 100 comprising the protrusion part 120′ may dispense with the need to provide a dedicate external support for the power contacts 130, 140 during the installation process (which may e.g. comprise a welding process as mentioned above).

The molded power semiconductor module 100 may therefore have a simplified installation process and may consequently offer cost reductions.

The protrusion part 120′ may for example be configured to support the power contacts 130, 140 against a mechanical force of 0.5N or more, or 1N or more, or 1.5N or more, or 2N or more. The protrusion part may for example have a thickness measured between the second side 122 of the molded body 120 and the second side 132, 142 of the power contacts 130, 140 of 0.5 mm or more, or 1 mm or more, or 1.5 mm or more, or 2 mm or more, or 5 mm or more. The protrusion part 120 may cover more than 50% or more than 70% or more than 90% or it may cover 100% of the surface area of the second sides 132, 142 of the power contacts 130, 140.

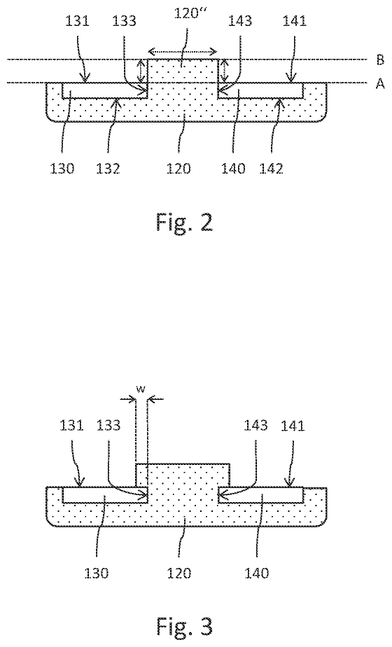

FIG. 2 shows a sectional view of a specific example of the molded power semiconductor module 100 along the line A-A′ in FIG. 1A.

As shown in FIG. 2, the first and second power contacts 130, 140 may also comprise lateral sides 133, 143 connecting the first and second sides 131, 132, respectively 141, 142. Furthermore, a lateral side 133 of the first power contact 130 is arranged opposite a lateral side 143 of the second power contact 140.

In the example shown in FIG. 2, the molded body 120 completely shields the opposite lateral sides 133, 143 from one another such that a creepage distance between the first and second power contacts 130, 140 is increased. In other words, the molded body 120 may comprise a ridge part 120″ which is arranged between the opposite lateral sides 133, 143 of the power contacts 130, 140. The first sides 131, 141 of the power contacts 130, 140 are arranged in a first plane (plane A) and the ridge part 120″ extends up to a second plane (plane B) which is arranged above the first plane. The creepage distance between the power contacts 130, 140 is increased by twice the height difference between the two planes A and B. As shown in FIG. 2, the molded body 120 does not necessarily have to extend above plane A at the outer lateral sides of the power contacts 130, 140 because no creepage distance has to be increased there.

In order to couple the molded. power semiconductor module 100 comprising the ridge part 120″ to an external appliance (e.g. a bus bar), it may be necessary that the external appliance comprises contacts with a fitting shape which take into account the presence of the ridge part 120″.

According to an example, the molded power semiconductor module 100 does not comprise the ridge part 120″, meaning that the molded body 120 does not extend above the plane A between the power contacts 130, 140. In this case, the creepage distance between the power contacts 130, 140 is not increased.

FIG. 3 shows a sectional view of a further specific example of the molded power semiconductor module 100 along the line A-A′ in FIG. 1A.

As shown in the specific example of FIG. 3, the molded body 120 may at least partially cover an edge portion of the first side 131, 141 of the first and second power contacts 130, 140. By covering the edge portion of the first sides 131, 141, the creepage distance between the power contacts 130, 140 may be increased further.

The edge portion of the first sides 131, 141 of the power contacts 130, 140 that is covered by the molded body 120 may for example have a width w of 0.1 mm or more, or 0.3 mm or more, or 0.6 mm or more, or 0.9 mm or more, or 1.5 mm or more, or 2 mm or more, or 5 mm or more.

Edge portions along a single lateral side 133 143 of a power contact 130, 140 may be covered by the molded body 120, as shown in the example of FIG. 3. However, it is also possible that edge portions along both lateral sides 133, 143 of a power contact 130, 140 are covered by the molded body 120.

Furthermore, it should be noted that in FIG. 1A, a distal end of the power contacts 130, 140 (i.e. the lateral side 133, 143 arranged at the bottom in FIG. 1A) is exposed from the molded body 120. It is however also possible that the molded body 120 covers this lateral side 133, 143 as well.

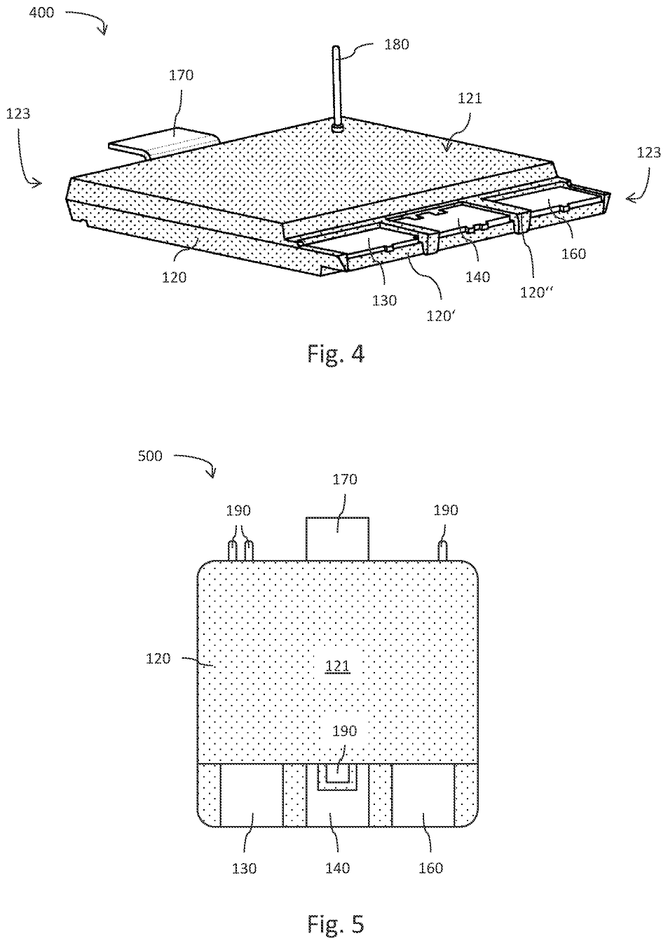

FIG. 4 shows a perspective view of a further molded power semiconductor module 400 which may be similar or identical to the molded power semiconductor module 100, except for the differences described in the following.

The molded power semiconductor module 400 comprises the first and second power contacts 130, 140 and it further comprises a third power contact 160. The third power contact 160 may be arranged laterally next to the second power contact 140 at the same lateral side 123 of the molded body 120. The power contacts 130, 140 and 160 may e.g. be coplanar with each other. The protrusion part 120′ may be configured to support all three power contacts 130, 140 and 160 as explained further above.

According to an example, the first and third power contacts 130, 160 are configured to carry a positive supply voltage and the second power contact 140 is configured to carry a negative supply voltage. According to another example, it is the other way around.

The molded power semiconductor module 400 may further comprise a fourth power contact 170. The fourth power contact 170 may be arranged at a lateral side 123 of the molded body 120 that is opposite to the lateral side 123 which comprises the first, second and third power contacts 130, 140 and 160. The fourth power contact 170 may for example be configured as a phase contact of the molded power semiconductor module 400.

According to an example, the fourth power contact 170 is not supported by a protrusion part 120′ of the molded body 120. In other words, both the first and the second side of the fourth power contact 170 are exposed from the molded body 120. However, it is also possible that the fourth power contact 170 is supported by a protrusion part 120′, similar to the first, second and third power contacts 130, 140 and 160.

The molded power semiconductor module 400 may further comprise one or more control or sensing contacts 180. The control or sensing contact (s) 180 may for example be arranged at the first side 121 of the molded body 120. The control or sensing contacts 180 may essentially be arranged in a vertical direction with respect to an orientation of the power contacts 130-170. The control or sensing contacts 180 may be configured to provide control signals for controlling the power semiconductor die(s) 110 of the molded power semiconductor module 400 and/or to output sensing signals, e.g. for temperature sensing. According to an example, the control or sensing contacts 180 comprise pins, e.g. press fit pins.

FIG. 5 shows a plan view of a further molded power semiconductor module 500 which may be similar or identical to the molded power semiconductor modules 100 or 400, except for the differences described in the following.

In particular, the molded power semiconductor module 500 also comprises one or more testing contacts 190 exposed from the molded body 120. The one or more testing contacts 190 are configured to provide electrical connections to top side electrodes of the one or more power semiconductor dies 110 for electrical testing.

The top side electrodes are those electrodes of the power semiconductor die (s) 110 that face towards the first side 121 of the molded body 120. After the molded body 120 has been formed, the top side electrodes may be inaccessible from the outside. By providing the testing contacts 190 which are coupled to the top side electrodes, an electrical functionality test of the top side electrodes can be performed.

According to an example, one or more of the testing contacts 190 are arranged coplanar with the power contacts 130, 140 and 160. As shown in FIG. 5, a testing contact 190 may be arranged in a cutout area of a power contact (the second power contact 140 in FIG. 5). The power contacts 130-170 and the testing contacts 190 may for example be parts of the same leadframe.

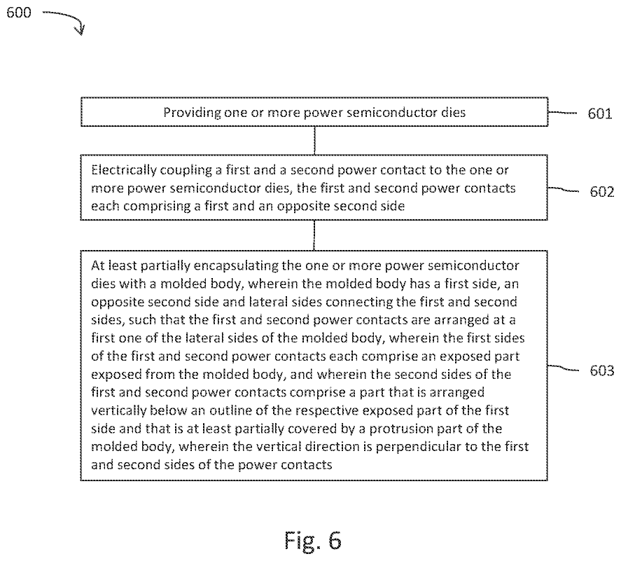

FIG. 6 is a flow chart of a method 600 for fabricating a molded power semiconductor module. The method 600 may for example be used to fabricate the molded power semiconductor modules 100, 400 and 500.

The method 600 comprises at 601 a process of providing one or more power semiconductor dies, at 602 a process of electrically coupling a first and a second power contact to the one or more power semiconductor dies, the first and second power contacts each comprising a first and an opposite second side, and at 603 a process of at least partially encapsulating the one or more power semiconductor dies with a molded body, wherein the molded body has a first side, an opposite second side and lateral sides connecting the first and second sides, such that the first and second power contacts are arranged at a first one of the lateral sides of the molded body, wherein the first sides of the first and second power contacts each comprise an exposed part exposed from the molded body, and wherein the second sides of the first and second power contacts comprise a part that is arranged vertically below an outline of the respective exposed part of the first side and that is at least partially covered by a protrusion part of the molded body, wherein the vertical direction is perpendicular to the first and second sides of the power contacts.

In the following, the molded power semiconductor module as well as the method for fabricating a molded power semiconductor module are further explained using specific examples.

Example 1 is a molded power semiconductor module, comprising: one or more power semiconductor dies, a molded body at least partially encapsulating the one or more power semiconductor dies, the molded body having a first side, an opposite second side and lateral sides connecting the first and second sides, a first and a second power contact arranged laterally next to each other at a first one of the lateral sides of the molded body and electrically coupled to the one or more power semiconductor dies, the first and second power contacts each comprising a first and an opposite second side, wherein the first sides of the first and second power contacts each comprise an exposed part exposed from the molded body, and wherein the second sides of the first and second power contacts comprise a part that is arranged vertically below an outline of the respective exposed part of the first side and that is at least partially covered by a protrusion part o the molded body, wherein the vertical direction is perpendicular to the first and second sides of the power contacts.

Example 2 is the molded power semiconductor module of example 1, wherein the first and second power contacts also comprise lateral sides connecting the first and second sides, wherein a lateral side of the first power contact is arranged opposite lateral side of the second power contact, and wherein the molded body completely shields the opposite lateral sides from one another such that a creepage distance between the first and second power contacts is increased.

Example 3 is the molded power semiconductor module of one of the preceding examples, wherein the first power contact is configured to carry a positive supply voltage and the second power contact is configured to carry a negative supply voltage.

Example 4 is the molded power semiconductor module of one of the preceding examples, wherein the protrusion part is configured to support the respective one of the first and second power contacts against a mechanical force of IN or more pressing down onto the first side of the respective one of the first and second power contacts.

Example 5 is the molded power semiconductor module of one of the preceding examples, wherein a thickness of the protrusion part of the molded body is 1 mm or more, the thickness being measured perpendicular to the first and second sides of the power contacts.

Example 6 is the molded power semiconductor module of one of the preceding examples, further comprising: at least one further power contact arranged at a second one of the lateral sides of the molded body, wherein the at least one further power contact is configured as a phase contact of the molded power semiconductor module.

Example 7 is the molded power semiconductor module of one of the preceding examples, further comprising: testing contacts exposed from the molded body and configured to provide electrical connections to top side electrodes of the one or more power semiconductor dies for electrical testing, wherein the power contacts and the testing contacts are leadframe parts.

Example 8 is the molded power semiconductor module of one of the preceding examples, further comprising: control or sensing contacts exposed from the first side of the molded body.

Example 9 is the molded power semiconductor module of one of the preceding examples, wherein the first and second power contacts are coplanar.

Example 10 is the molded power semiconductor module of one of the preceding examples, wherein the molded body also at least partially covers an edge portion of the first side of the first and second power contacts.

Example 11 is the molded power semiconductor module of one of the preceding examples, wherein the second side of the molded body is configured to be arranged over a heatsink.

Example 12 is a method for fabricating a molded power semiconductor module, the method comprising: providing one or more power semiconductor dies, electrically coupling a first and a second power contact to the one or more power semiconductor dies, the first and second power contacts each comprising a first and an opposite second side, and at least partially encapsulating the one or more power semiconductor dies with a molded body, wherein the molded body has a first side, an opposite second side and lateral sides connecting the first and second sides, such that the first and second power contacts are arranged at a first one of the lateral sides of the molded body, wherein the first sides of the first and second power contacts each comprise an exposed part exposed from the molded body, and wherein the second sides of the first and second power contacts comprise a part that is arranged vertically below an outline of the respective exposed part of the first side and that is at least partially covered by a protrusion part of the molded body, wherein the vertical direction is perpendicular to the first and second sides of the power contacts.

Example 13 is the method of example 12, wherein the protrusion part is configured to support the respective one of the first and second power contacts against a mechanical force of 1N or more pressing down onto the first side of the respective one of the first and second power contacts.

Example 14 is an apparatus with means for performing the method according to example 12 or 13.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though riot structurally equivalent to the disclosed structure which performs the function in the herein illustrated exemplary implementations of the disclosure.

What is claimed is:

1. A molded power semiconductor module, comprising:
one or more power semiconductor dies;
a molded body at least partially encapsulating the one or more power semiconductor dies, the molded body having a first side, an opposite second side, and lateral sides connecting the first and second sides; and
a first and a second power contact arranged laterally next to each other at a first one of the lateral sides of the molded body and electrically coupled to the one or more power semiconductor dies, the first and second power contacts each comprising a first and an opposite second side,
wherein the first sides of the first and second power contacts each comprise an exposed part exposed from the molded body,
wherein the second sides of the first and second power contacts each comprise a part that is arranged in a vertical direction below an outline of the respective exposed part of the first side and fiat is at least partially covered by a protrusion part of the molded body,
wherein the vertical direction is perpendicular to the first and second sides of the first and second power contacts.

2. The molded power semiconductor module of claim 1, wherein the first and second power contacts further comprise lateral sides connecting the first and second sides, wherein a lateral side of the first power contact is arranged opposite a lateral side of the second power contact, and wherein the molded body completely shields the opposite lateral sides from one another such that a creepage distance between the first and second power contacts is increased.

3. The molded power semiconductor module of claim 1, wherein the first power contact is configured to carry a positive supply voltage and the second power contact is configured to carry a negative supply voltage.

4. The molded power semiconductor module of claim 1, wherein the protrusion part of the molded body is configured to support the respective one of the first and second power contacts against a mechanical force of 1N or more pressing down onto the first side of the respective one of the first and second power contacts.

5. The molded power semiconductor module of claim 1, wherein a thickness of the protrusion part of the molded body is 1 mm or more, the thickness being measured perpendicular to the first and second sides of the power contacts.

6. The molded power semiconductor module of claim 1, further comprising:
at least one further power contact arranged ac a second one of the lateral sides of the molded body,
wherein the at least one further power contact is configured as a phase contact of the molded power semiconductor module.

7. The molded power semiconductor module of claim 1, further comprising:
testing contacts exposed from the molded body and configured to provide electrical connections to top side electrodes of the one or more power semiconductor dies for electrical testing,
wherein the first and second power contacts and the testing contacts are leadframe parts.

8. The molded power semiconductor module of claim 1, further comprising:
control or sensing contacts exposed from the first side of the molded body.

9. The molded cower semiconductor claim 1, wherein the first and second power contacts are coplanar.

10. The molded power semiconductor module of claim 1, wherein the molded body at least partially covers an edge portion of the first side of the first and second power contacts.

11. The molded power semiconductor module of claim 1, wherein the second side of the molded body is configured to be arranged over a heatsink.

12. A method for fabricating a molded power semiconductor module, the method comprising:
providing one or more power semiconductor dies;
electrically coupling a first and a second power contact to the one or more power semiconductor dies, the first and second power contacts each comprising a first and an opposite second side; and
at least partially encapsulating the one or more power semiconductor dies with a molded body,
wherein the molded body has a first side, an opposite second side, and lateral sides connecting the first and second sides, such that the first and second power contacts are arranged at a first one of the lateral sides of the molded body,
wherein the first sides of the first and second power contacts each comprise an exposed part exposed from the molded body,
wherein the second sides of the first and second power contacts each comprise a part that as arranged in a vertical direction below an outline of the respective exposed part of the first side and that is at least partially covered by a protrusion part of the molded body,
wherein the vertical direction is perpendicular to the first and second sides of the power contacts.

13. The method of claim 12, wherein the protrusion part of the molded body is configured to support the respective one of the first and second power contacts against a mechanical force of 1N or more pressing down onto the first side of the respective one of the first and second power contacts.
